(19) United States
(12) Patent Application Publication
(10) Pub. No.: US 2022/0267901 A1
(43) Pub. Date: Aug. 25, 2022

(54) WAFER-HOLDING DEVICE AND DEPOSITION EQUIPMENT USING THE SAME

(71) Applicant: SKY TECH INC., Hsinchu County (TW)

(72) Inventor: JING-CHENG LIN, Hsinchu County (TW)

(21) Appl. No.: 17/517,441

(22) Filed: Nov. 2, 2021

(30) Foreign Application Priority Data
Feb. 22, 2021 (TW) 110106092

(51) Int. Cl. C23C 16/458

(52) U.S. Cl. CPC C23C 16/4585; C23C 16/4581

(57) ABSTRACT

The present disclosure provides a wafer-holding device and a deposition equipment using the same, wherein the wafer-holding device includes a carrier, a first-lid ring and a second-lid ring. The carrier has a carrying surface for carrying a wafer thereon, and includes a first aligner disposed to enclose the carrying surface. The second-lid ring is connected to the first-lid ring, and includes a second aligner. The first-lid ring has a circumference larger than that of the second-lid ring, for carrying the second-lid ring thereon. The carrier is movable, and when the carrier carries the wafer thereon toward the lid rings, the first aligner thereon contacts, engages with the second aligner of the second-lid ring, thereby the second aligner is positioned to contact a specific area of the wafer and hold the wafer on the carrier, for the deposition equipment to perform a thin-film-deposition process to the wafer.

This non-provisional application claims priority claim under 35 U.S.C. § 119(a) on Taiwanese invention application No. 110106092 filed on Feb. 22, 2021, the entire contents of which are incorporated herein by reference.

### TECHNICAL FIELD

The present disclosure relates to a wafer-holding device for holding a wafer on a carrier thereof, and also a deposition equipment using the wafer-holding device for performing a thin-film-deposition process to the wafer.

### BACKGROUND

Deposition equipments, such as chemical vapor deposition (CVD), physical vapor deposition (PVD) and atomic-layer deposition (ALD) equipments, those are commonly employed in manufacturing of integrated circuits, light-emitting diodes and displays, etc.

A deposition equipment mainly includes a chamber and a wafer carrier, wherein a wafer carrier is positioned within the chamber for carrying at least one wafer. For example in PVD, it is required to dispose a target material in the chamber and have the target material facing the wafer on the wafer carrier. When performing the PVD, the wafer is held and fastened on the wafer carrier by a holding device, thereafter a noble gas and/or reactive gas may be transferred into the chamber, meanwhile the target material and the wafer carrier are applied with bias electricity, and moreover, the wafer carrier can also heat up the wafer carried thereon. The noble gas within the chamber is ionized by an effect of high-voltage electric field, such that to form ionized gas. Then, the ionized noble gas is attracted by the bias applied on the target material to bombard the target material. On next, atoms or molecules splashed, flying out from the target material are attracted by the bias electricity on the wafer carrier, and deposited on a surface of the heated-up wafer to form a thin film on the surface of the wafer.

Generally, common deposition equipments from industrial makers are merely adapted to process wafers with one single size. As for performing deposition to process a wafer with different size, many reconfigurations are required to apply on a structure the currently using deposition equipment, or even must to purchase a different type of deposition equipment, which can cause inconvenience in use, and large cost in manufacturing process.

### SUMMARY

As described in the background, the conventional deposition equipments are commonly adapted to wafers in one single size only, therefore inconvenient for the use and costly for the manufacturing process. Hence, the present disclosure provides a new wafer-holding device and a deposition equipment using the same, which can be adapted to hold, fasten wafer(s) with two or more different sizes and perform deposition, such that to improve utility of the wafer-holding device and the deposition equipment, furthermore to reduce and save the cost.

An object of the present disclosure is to provide a wafer-holding device, which mainly includes a wafer carrier (hereafter as “carrier”), a first-lid ring and a second-lid ring, wherein the carrier is for carrying at least one wafer. The first-lid ring is for carrying the second-lid ring, wherein the second-lid ring has a circumference or radius smaller than that of the first-lid ring and is placed inside of the first-lid ring. When the carrier moves the wafer carried on thereby toward the second-lid ring, the second-lid ring contacts the wafer, and fasten the wafer on the carrier.

According to the present disclosure, the carrier and the second-lid ring are disposed with aligners those correspond to each other. When the carrier moves to approach the second-lid ring, the aligners aid to guide and align the second-lid ring with the carrier, such that to position the second-lid ring on the carrier for precisely contacting and holding the wafer on the carrier.

In practical use, the second-lid ring can be removed from the first-lid ring, and the first-lid ring with larger radius or circumference can fasten a wafer with a larger size on the carrier. Moreover, when the second-lid ring is placed on the first-lid ring, the second-lid ring with smaller radius or circumference is fastened on the carrier, such that the wafer-holding device is adapted to fasten wafers with two different sizes and perform thin-film deposition. Additionally, the second-lid ring has a weight less than that of the first-lid ring or a total weight of the first-lid ring and the second-lid ring, thereby to avoid damaging the wafer while fastening on the carrier.

Also to mention that the wafer may be formed with a slightly bulging-up side edge, such that when the wafer is moved by carrier to contact the second-lid ring, the wafer may slightly push up and move the second-lid ring upward related to the first-lid ring. For that, the second-lid ring has a weight lighter than that of the first-lid ring, or lighter a total weight of the first-lid ring and the second-lid ring together, in order to prevent crushing, damaging the wafer when contacting and holding the wafer.

An object of the present disclosure is to provide a wafer-holding device, which mainly includes a carrier and a carrying member. The carrier has a carrying surface for carrying at least one wafer, and the carrying member is disposed on the carrier and below the wafer.

The carrying member is connected to at least one elevating unit, and moved by the elevating unit related to the carrier. When the carrying member is driven by the elevating unit to leave the carrier, the carrying member moves the wafer to leave the carrying surface of the carrier, to allow a robotic arm to take out the wafer on the carrying member, or to place the wafer on the carrying member. Thereafter the elevating unit can drive the carrying member toward the carrier, and place the wafer on the carrying surface on the carrier.

To achieve the abovementioned object, the present disclosure provides a wafer-holding device, for carrying and holding at least one wafer. The wafer-holding device includes a carrier, a first-lid ring and second-lid ring. The carrier has a first aligner and a carrying surface for carrying the wafer, wherein the first aligner encloses a periphery of the carrying surface. The first-lid ring is disposed above the carrier. The second-lid ring is connected to the first-lid ring and has a second aligner corresponding to the first aligner. The first-lid ring has a circumference greater than that of the second-lid ring and is for carrying the second-lid ring. When the carrier moves toward the second-lid ring, the second-lid ring contacts the wafer carried by the carrier, and the second-lid ring has the second aligner contacting the first aligner of the carrier and thereby aligning with the carrier.

The present disclosure also provides a deposition equipment, which includes a chamber, at least one blocking member, a wafer-holding device, and a support member. The chamber includes a containing space. The blocking member is positioned within the containing space of the chamber, wherein the blocking member has an end formed with an annular flange, the annular flange is formed with an opening on a radial-inner side thereof. The wafer-holding device is for carrying and holding at least one wafer, and includes a carrier, a first-lid ring and second-lid ring. The carrier has a first aligner and a carrying surface for carrying the wafer, wherein the first aligner encloses the carrying surface. The first-lid ring is disposed above the carrier. The second-lid ring is connected to the first-lid ring and has a second aligner corresponding to the first aligner. The first-lid ring has a circumference greater than that of the second-lid ring and is for carrying the second-lid ring. When the carrier moves toward the second-lid ring, the second-lid ring contacts the wafer carried by the carrier, and the second-lid ring has the second aligner contacting the first aligner of the carrier and thereby aligning with the carrier. The support member is connected to the carrier for moving the carrier related to the blocking member, wherein when the support member moves the carrier toward the blocking member, the second-lid ring contacts the wafer, and the second aligner of the second-lid ring contacts first aligner of the carrier to align and position the second-lid ring and the carrier.

Moreover, the present disclosure provide the aforementioned a wafer-holding device and a deposition equipment, wherein the first-lid ring includes at least one third aligner, the second-lid ring includes at least one fourth aligner. The second aligner and the fourth aligner are disposed on a bottom surface of the second-lid ring, in a manner that the fourth aligner is positioned radially-outer than the second aligner. When the second-lid ring is placed to connect to the first-lid ring, fourth aligner contacts the third aligner for align and positioning the second-lid ring on the first-lid ring.

The present disclosure also provide the aforementioned a wafer-holding device and a deposition equipment, which further includes a ring member connected to the carrier and enclosing the periphery of the carrying surface thereof. The first-lid ring includes at least one fifth aligner, the ring member includes at least one sixth aligner. When the ring member moves with the carrier to contact the first-lid ring, the fifth aligner contacts the sixth aligner for aligning the ring member with the first-lid ring.

### BRIEF DESCRIPTION OF THE DRAWINGS

The structure as well as preferred modes of use, further objects, and advantages of this present disclosure will be best understood by referring to the following detailed description of some illustrative embodiments in conjunction with the accompanying drawings, in which:

FIG. 1 is a schematic perspective exploded view illustrating a wafer-holding device according to one embodiment of the present disclosure.

FIG. 2 is a schematic fragmentary sectional view illustrating the wafer-holding device which is adapted to a deposition equipment and which has an second-lid ring of dismounted therefrom, according to one embodiment of the present disclosure.

FIG. 3 is a schematic fragmentary sectional view illustrating the wafer-holding device which is fully aligned and positioned in the deposition equipment, according to one embodiment of the present disclosure.

FIG. 4˜FIG. 6 are schematic fragmentary perspective sectional views illustrating the wafer-holding device operated into different position states within the deposition equipment, according to one embodiment of the present disclosure.

FIG. 7 is a schematic sectional view illustrating the deposition equipment according to one embodiment of the present disclosure.

### DETAILED DESCRIPTION OF THE PREFERRED EMBODIMENTS

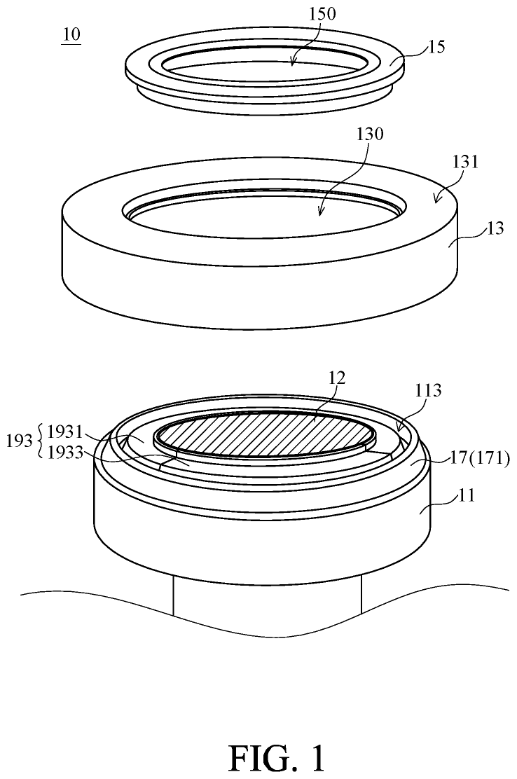

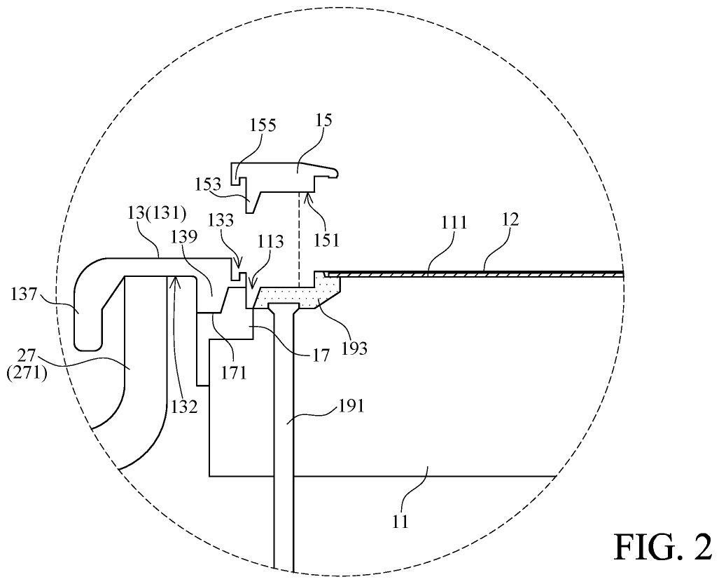

Referring to FIG. 1 and FIG. 2, which are a schematic perspective exploded view illustrating a wafer-holding device, and a schematic fragmentary sectional view illustrating the wafer-holding device which is adapted to a deposition equipment and which has an second-lid ring of dismounted therefrom, according to one embodiment of the present disclosure. As shown by FIGs, the wafer-holding device 10 is for carrying and fastening at least one wafer 12, and mainly includes at least one wafer carrier 11, an first-lid ring 13 and an second-lid ring 15, wherein the first-lid ring 13 and the second-lid ring 15 are positioned above the carrier 11 and the wafer 12.

The carrier 11 includes a carrying surface 111, for carrying the wafer 12. The first-lid ring 13 and the second-lid ring 15 are annular from a top view angle. The first-lid ring 13 has a maximum circumference and/or maximum radius larger than that of the second-lid ring 15. The second-lid ring 15 is positioned above the first-lid ring 13, and the second-lid ring 15 is connected to and carried on by the first-lid ring 13. When the carrier 11 moves toward the first-lid ring 13 and/or the second-lid ring 15, the second-lid ring 15 contacts an edge of the wafer 12 which is carried on by the carrier 11, to fasten the wafer 12 on the carrying surface 111 of the carrier 11.

Specifically, the first-lid ring 13 includes a first opening 130, and the second-lid ring 15 includes a second opening 150. The first opening 130 has a radius, circumference and/or area larger than that of the second opening 150, and the second-lid ring 15 has a maximum radius and/or maximum circumference larger than that of the first opening 130. Therefore, the second-lid ring 15 can be disposed or placed on a radial-inner side of the first-lid ring 13, wherein when the second-lid ring 15 is placed on the first-lid ring 13, a portion on a radial-inner side of the second-lid ring 15 protrudes from the radial-inner side of the first-lid ring 13, to partially cover the first opening 130, such as a portion of the second-lid ring 15 protrudes radially inward from the first-lid ring 13 to partially cover the first opening 130 of the first-lid ring 13.

The second-lid ring 15 has a weight less than that of the first-lid ring 13, wherein the second-lid ring 15 or both of the first-lid ring 13 and the second-lid ring 15 apply a relatively small force on the wafer 12, such that to prevent the wafer 12 from receiving an excessive pressure/stress and resulting in damage thereof. Therefore, the wafer-holding device 10 according the present disclosure is especially adapted to fasten wafers 12 with relative thin thickness on the carrier 11.

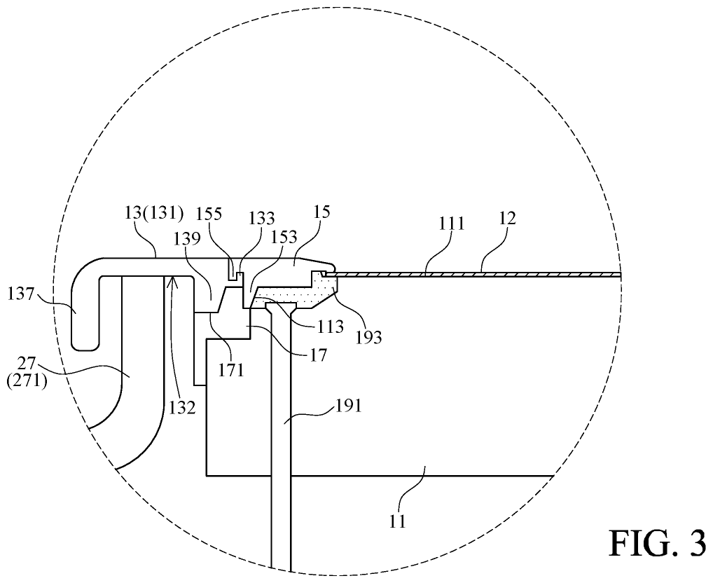

To be specific, as shown in FIG. 3 and FIG. 5, some wafers 12 may have an side edge formed bulging-up during production thereof, such that when the carrier 11 carries a wafer 12 bulging-up at the edge toward the first-lid ring 13 and/or the second-lid ring 15, the second-lid ring 15 then contacts and presses on the wafer 12, and hence to hold, fasten the wafer 12 on the carrying surface 111 of the carrier 11. Meanwhile, the bulging-up side edge of the wafer 12 may push up, move the second-lid ring 15 upward related to the first-lid ring 13, such that the second-lid ring 15 may be slightly separate from the first-lid ring 13. In this case, the wafer 12 with bulging-up side edge has no need to bear a total weight of the first-lid ring 13 and the second-lid ring 15 both but only the weight of the second-lid ring 15, therefore such configuration is able to prevent damage to the wafer caused by excessive weight pressure.

In one embodiment of the present disclosure, the carrier 11 further includes at least one first aligner 113 which encloses a periphery of the carrying surface 111, and the second-lid ring 15 includes at least one second aligner 153 which corresponds to the first aligner 113 of the carrier 11.

To be specific, when the second-lid ring 15 and the carrier 11 get closer to each other, the second aligner 153 of the second-lid ring 15 also contacts and aligns with the first aligner 113 of the carrier 11, and hence the second-lid ring 15 is positioned on the carrier 11. By virtue of the first aligner 113 and the second aligner 153, the second-lid ring 15 can be precisely positioned on the carrier 11, to contact a specific area of the wafer 12 (e.g. the side edge) on the carrier 11, and also to secure and hold the wafer 12 thereon.

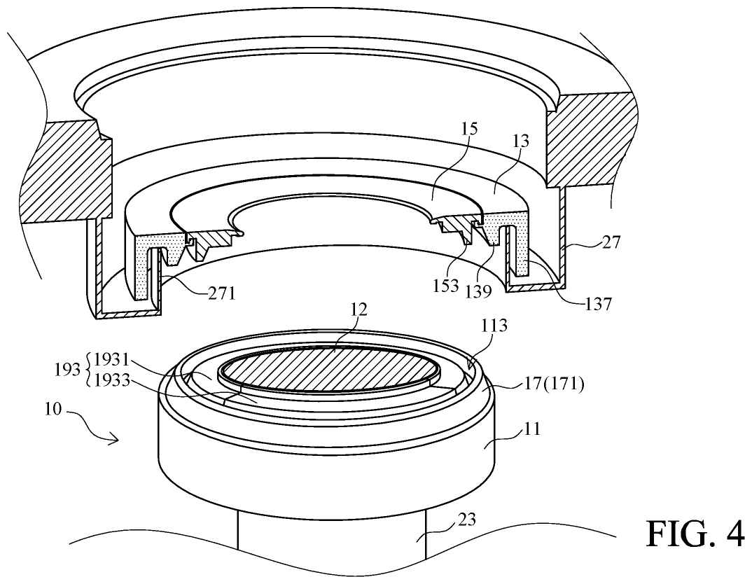

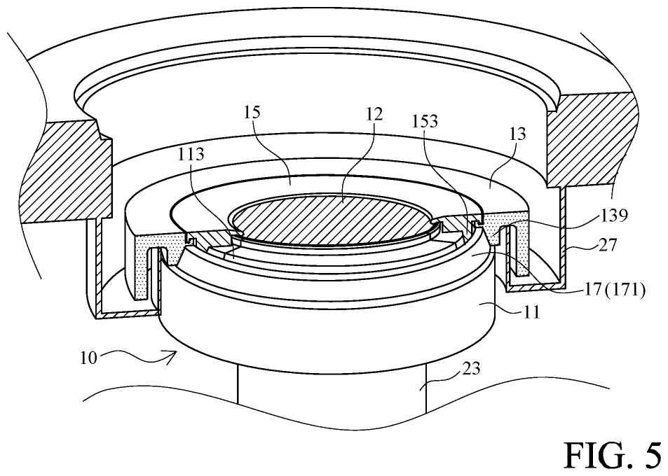

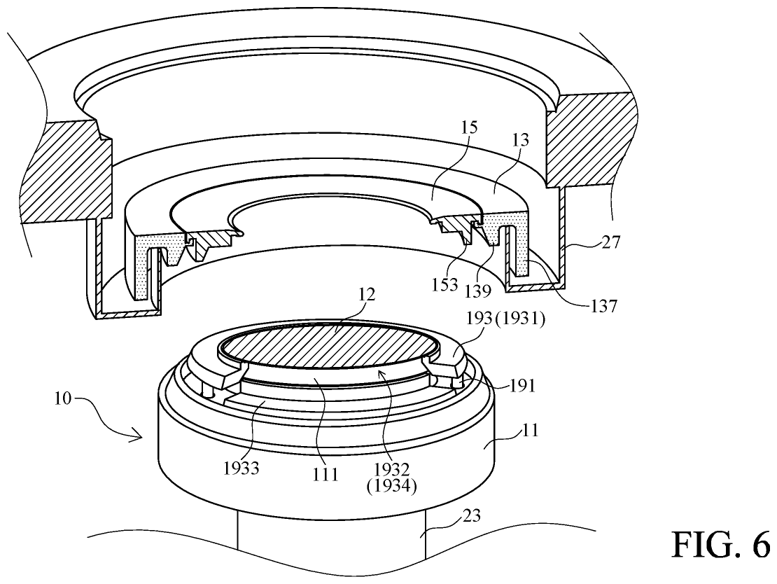

In one embodiment of the present disclosure, the first aligner 113 of the carrier 11 may be a cavity formed with an inclined wall, on the other side, the second aligner 153 of the second-lid ring 15 may be a protrusion also formed with an inclined surface, as shown in FIG. 2. For example, as shown in FIG. 4, the first aligner 113 of carrier 11 may be an annular cavity formed with the inclined wall surface, and disposed to enclose the periphery of the carrying surface 111, and on the other side, the second aligner 153 may be an annular protrusion which is formed with the inclined surface and which is disposed on a bottom surface of the second-lid ring 15. With such structure, when the second-lid ring 15 and the carrier 11 contact each other, the second aligner 153 has the inclined surface thereof guided by the inclined wall surface of the first aligner 113, and hence engaged and aligned therewith.

Alternatively, in another embodiment, the first aligner 113 of the carrier 11 may be configured as an annular incline surface which is directly connected to and surrounds the periphery of the carrying surface 111, such that to guide and align with the second aligner 153 of the second-lid ring 15 as well.

In one embodiment of the present disclosure, the first-lid ring 13 includes at least one third aligner 133, and the second-lid ring 15 includes at least one fourth aligner 155. In more detail, for the second-lid ring 15, the fourth aligner 155 is disposed on the bottom surface 151 radially outer than the second aligner 153. Such that, when the second-lid ring 15 is placed on and connected to the first-lid ring 13, the fourth aligner 155 contacts and aligns, engages with the third aligner 133, thereby to position and fasten the second-lid ring 15 on the first-lid ring 13.

As shown in FIG. 2, the third aligner 133 of the first-lid ring 13 may include at least one cavity and/or at least one protrusion, which is(are) disposed on a top surface 131 of the first-lid ring 13. On the other side, the fourth aligner 155 of the second-lid ring 15 may also include at least one cavity and/or at least one protrusion, which is(are) disposed on the bottom surface 151 of the second-lid ring 15. Also, the cavities and the protrusions of the first-lid ring 13 and the second-lid ring 15 may all be formed annular, for example.

To be specific, the third aligner 133 of the first-lid ring 13 includes an annular cavity, and an annular protrusion between the cavity thereof and the first aligner 113 of the carrier 11. On the other side, the fourth aligner 155 of the second-lid ring 15 includes an annular protrusion, and an annular cavity between the annular protrusion thereof and the second aligner 153. Also, the cavity of the third aligner 133 corresponds to and engages with the protrusion of the fourth aligner 155, the protrusion of the third aligner 133 corresponds to and engages with the cavity of the fourth aligner 155, thereby, the second-lid ring 15 can be guided and positioned on the first-lid ring 13.

The cavity of the third aligner 133 corresponds to the protrusion of the fourth aligner 155, the protrusion of the third aligner 133 corresponds to the cavity of the fourth aligner 155, such that, when the second-lid ring 15 is placed to connect to the first-lid ring 13, the corresponding cavities and protrusions of the third aligner 133 and the fourth aligner 155 guide and engage with each other, thereby to align and position the second-lid ring 15 on the first-lid ring 13.

Moreover, the first-lid ring 13 has a bottom surface 132 disposed with at least one rim 137 and at least one fifth aligner 139, wherein the both of the lid rim 137 and the fifth aligner 139 may be annular protrusions, and wherein the fifth aligner 139 is formed with an inclined surface. Also, the lid rim 137 is disposed radially outer than the fifth aligner 139, and may be disposed at or nearby an outmost edge of the first-lid ring 13. On the other side, the carrier 11 may include a sixth aligner 171 disposed radially outer than the first aligner 113, wherein the sixth aligner 171 is formed as an annular cavity which has an inclined wall corresponding to the inclined surface of the fifth aligner 139 of the first-lid ring 13. Such that, the fifth aligner 139 and the sixth aligner 171 can aid to align, position the first-lid ring 13 and the carrier 11 to each other as well.

In practical use, the second-lid ring 15 can be placed on the first-lid ring 13, to fasten a wafer 12 with a smaller size on the carrier 11 via the second-lid ring 15. Furthermore, the second-lid ring 15 can also be removed from the first-lid ring 13, to fasten a wafer 12 with a larger size on the carrier 11 via the first-lid ring 13. Also, when fastening the wafer 12 with larger size on the carrier 11 via the first-lid ring 13, the carrier 11 may also be required to replace or dispose with other additional components.

In one embodiment the present disclosure, the wafer-holding device 10 may include an ring member 17, wherein the ring member 17 is connected to the carrier 11 and disposed to surround the carrying surface 111 of the carrier 11 and/or wafer 12, such as the ring member 17 be mounted on a portion of the carrier 11, as shown in FIG. 2.

In this embodiment, as shown in FIG. 2 and FIG. 3, the ring member 17 surrounds the carrier 11 and such that to form the first aligner 113 (cavity) therebetween, moreover, the sixth aligner 171 is formed on the ring member 17. With such structure, when the carrier 11 moves to approach the first-lid ring 13, the third aligner 133 (protrusion) is guided to engage with the first aligner 113 (cavity), the fifth aligner 139 (protrusion) is guided to engage with sixth aligner 171 of the ring member 17 on the carrier 11, thereby the first-lid ring 13 aligns and engages with the carrier 11 and the ring member 17 thereon.

As described in the abovementioned embodiments, by virtue of the carrier 11 disposed with the first aligner 113, and the second-lid ring 15 disposed with the second aligner 153, the wafer-holding device 10 is able to precisely align and engage the second-lid ring 15 with the carrier 11. Without those corresponding aligners between the carrier 11 and the second-lid ring 15, such as to have the first aligner 113 and the second aligner 153 omitted, even though the second-lid ring 15 still can be aligned and engaged with the carrier 11 via the first-lid ring 13, by having the fourth aligner 155 engaged with the third aligner 133, and having the fifth aligner 139 engaged with the sixth aligner 171 on the carrier 11. However, such indirect connection and engagement between the second-lid ring 15 and the carrier 11 may result in a loose or unprecise relative positon therebetween, and such that the second-lid ring 15 is unable to accurately contact the specific area of the wafer 12 on the carrier 11, and hence unable to secure and hold still the wafer 12 on the carrying surface 111. Therefore, the first aligner 113 and the second aligner 153 for engaging the second-lid ring 15 and the carrier 11 are essential, for precisely securing and holding the wafer 12 on the carrying surface 111.

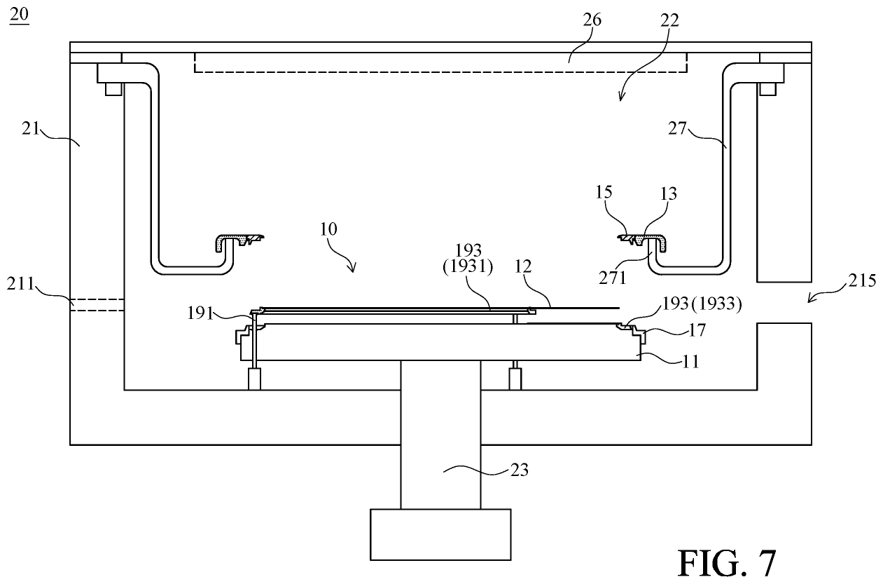

In one embodiment of the present disclosure, as shown in FIG. 6 and FIG. 7, the wafer-holding device 10 may include at least one elevating unit 191 and a carrying member 193. The carrying member 193 is disposed on the carrier 11 and below the wafer 12 carried on by the carrier 11, for example the carrying member 193 may have an annular appearance and be positioned on a radial-inner side of the ring member 17. The elevating unit 191 is connected to the carrying member 193 and the carrier 11, for moving the carrying member 193 related to the carrier 11. For example, the elevating unit 191 may be shaft(s) driven by a motor (via leadscrew or rack and pinion mechanism, etc.). Thereby, the elevating unit 191 can extend related to the carrying surface 111 of the carrier 11, and moves the carrying member 193 away from the carrier 11, hence to ascend and move the wafer 12 away from the carrying surface 111 of the carrier 11 via the carrying member 193.

In another embodiment of the present disclosure as shown in FIG. 3, the elevating unit 191 is connected to the carrier 11 and below the wafer 12 carried on by the carrier 11. With such configuration, the elevating unit 191 can extend related to the carrying surface 111 of the carrier 11, to ascend then to contact and push up the wafer 12 away from the carrying surface 111 of the carrier 11, such that there is no need to dispose the carrying member 193.

In practical use, as shown in FIG. 2, FIG. 4 and FIG. 7, the first-lid ring 13 may be placed on a tubular blocking member 27, wherein the blocking member 27 commonly has one end connected to and fastened within a chamber 21 for processing the wafer 12, and has another end formed with an opening. Moreover, the blocking member 27 has an inner flange 271 formed at the opening thereof, wherein the inner flange 271 protrudes radially inward from the another end of the blocking member 27 and bends into the opening, and be positioned between the lid rim 137 and the fifth aligner 139 of the first-lid ring 13 for carrying the first-lid ring 13. Such that, the first-lid ring 13 is within the opening of the blocking member 27, and hung on the inner flange 271.

The carrier 11 is connected to an extendable support member 23, wherein the support member 23 is for moving the carrier 11, related to the blocking member 27 also with the first-lid ring 13 and second-lid ring 15 carried thereon, as shown in FIG. 5. Such that, the second-lid ring 15 contacts the wafer 12 carried on by the carrier 11, to fasten and hold the wafer 12 on the carrier 11. The support member 23 may be power-transmittably connected to a motor via gear mechanism or leadscrew, etc., for example.

In one embodiment of the present disclosure as shown in FIG. 6, the support member 23 moves the carrier 11 away from the blocking member 27, the first-lid ring 13 and the second-lid ring 15. Thereafter, the elevating unit 191 may further move the carrying member 193 away from the carrier 11, thereby the carrying member 193 ascends to lift up the wafer 12 which was on the carrying surface 111 of the carrier 11, and to form a gap space 1934 between the wafer 12 and the carrying surface 111 of the carrier 11. A robotic arm (not shown) may enter the gap space 1934 below the wafer 12, to take out and extract the wafer 12 on the carrying member 193, or to place the wafer 12 on the carrying member 193.

After the robotic arm places the wafer 12 on the carrying member 193, the elevating unit 191 moves the carrying member 193 and the wafer 12 carried on thereby toward the carrying surface 111 of the carrier 11, such that to place the wafer 12 on the carrying surface 111 of the carrier 11, as shown in FIG. 4.

In another embodiment of the present disclosure, as shown in FIG. 6, the carrying member 193 includes a first-carrying portion 1931 and a second-carrying portion 1933, wherein the first-carrying portion 1931 includes a gap notch 1932, and the second-carrying portion 1933 is positioned within the gap notch 1932. To be specific, the carrying member 193 may have an annular appearance, both of the first-carrying portion 1931 and the second-carrying portion 1933 may be partially annular, so when the second carrying portion 1933 is positioned within the gap notch 1932 of the first-carrying portion 1931, both can form the carrying member 193 as a fully annular circle.

Moreover, the elevating unit 191 is only connected to the first-carrying portion 1931, wherein the elevating unit 191 can move the first-carrying portion 1931 and the wafer 12 to ascend away from the carrying surface 111 of the carrier 11, to facilitate the robotic arm to extract the wafer 12 from the gap notch 1932 of the first-carrying portion 1931, or to place the wafer 12 on the first-carrying portion 1931 via the gap notch 1932.

Referring to FIG. 7, which is a schematic sectional view of a deposition equipment, according to one embodiment of the present disclosure. As shown in FIG, the deposition equipment 20 includes at least one wafer-holding device 10 and a chamber 21, wherein the chamber 21 includes a containing space 22, and the wafer-holding device 10 is positioned within the containing space 22 for carrying at least one wafer 12.

The wafer-holding device 10 employed by the deposition equipment 20 in this embodiment, which is similar to the aforementioned embodiment shown in FIG. 1˜FIG. 6, and which mainly includes the carrier 11, the annular first-lid ring 13 and the second-lid ring 15.

Furthermore, the containing 22 of the chamber 21 is disposed with at least one of the aforementioned blocking member 27 therein, wherein the blocking member 27 is formed with the inner flange 271 for carrying the first-lid ring 13, and the first-lid ring 13 is for carrying the second-lid ring 15. Also to mention that the inner flange 271 at the opening of the blocking member 27, which is for the wafer 12 carried by the carrier 11 to enter and be held by the lid rings 13, 15, such that the deposition equipment 20 can then perform a deposition process (e.g. thin-film deposition) to the wafer 12 within the tubular blocking member 27, as shown in FIG. 5.

In one embodiment of the present disclosure, the deposition equipment 20 may be a physical-vapor-deposition equipment which has a target material 26 within the chamber 21, wherein the target material 26 faces the carrier 11 and/or the wafer 12. The chamber 21 is disposed with at least one gas inlet 211, wherein the gas inlet 211 is fluidly connected to the containing space 22 of the chamber 21, for transferring a process gas into the containing space 22 to perform a thin-film deposition. The process gas may be such as noble gas, or reaction gas. In addition, the chamber 21 may be disposed with a gas outlet (not shown) thereon, for extracting the gas within the chamber 21 via a pump.

The chamber 21 may further include a wafer passage 215, for transporting a wafer 12 into or extract the wafer 12 from the chamber 21, via the robotic arm. Also to mention that the elevating unit 19 is disposed to have the gap notch 1932 facing the wafer passage 215 when the first-carrying portion 1931 ascends from the carrying surface 111, such that to facilitate the robotic arm to place on the first-carrying portion 1931, or to extract out the wafer 12 therefrom.

In one embodiment of the deposition equipment 20 according to the present disclosure, the carrier 11 is connected to the aforementioned support member 23, for moving the carrier 11 related to the blocking member 27 and the first-lid ring 13 and the second-lid ring 15. As shown in FIG. 5, the support member 23 extends to move the carrier 11 toward and into the opening of the blocking member 27, thereby the second-lid ring 15 contacts the wafer 12 of the carrier 11, to fasten and hold the wafer 12 on the carrier 11, for the later-performed deposition process.

As shown in FIG. 6 and FIG. 7, the support member 23 can also return and move the carrier 11 away from the blocking member 27 and the first-lid ring 13 and the second-lid ring 15. Thereafter, the elevating unit 191 may further move the carrying member 193 or the first-carrying portion 1931 away from the carrier 11, thereby the carrying member 193 or the first-carrying portion 1931 ascends to lift up the wafer 12 which was on the carrying surface 111 of the carrier 11, and to form a gap space 1934 between the wafer 12 and the carrying surface 111 of the carrier 11, to facilitate the robotic arm to extract the wafer 12 on the carrying member 193, or to place a wafer 12 on the carrying member 193, via the wafer passage 215.

After the robotic arm places a wafer 12 on the carrying member 193 or the first carrying portion 1931, the elevating unit 191 moves the carrying member 193 and the wafer 12 carried thereon to descend toward the carrying surface 111 of the carrier 11, to place the wafer 12 on the carrying surface 111 of the carrier 11, as shown in FIG. 4.

Thereafter, the support member 23 can extend to move the carrier 11 and the wafer 12 thereon toward the blocking member 27, then to contact the first-lid ring 13 and/or the second-lid ring 15 hung on the blocking member 27, as shown in FIG. 5. When the second-lid ring 15 contacts the carrier 11, the first aligner 113 of the carrier 11 guides the second aligner 153 of the second-lid ring 15, such that the second-lid ring 15 is engaged and aligned with the carrier 11, then to contact a specific area (side edge) of the wafer 12 and hence to hold, secure the wafer 12 on the carrier 11.

The above disclosure is only the preferred embodiment of the present disclosure, and not used for limiting the scope of the present disclosure. All equivalent variations and modifications on the basis of shapes, structures, features and spirits described in claims of the present disclosure should be included in the claims of the present disclosure.

We claim:

1. A wafer-holding device, comprising:
a carrier for carrying at least one wafer and comprising at least one first aligner and a carrying surface for carrying the at least one wafer, wherein the at least one first aligner encloses a periphery of the carrying surface;
a first-lid ring positioned above the carrier; and
a second-lid ring connected to the first-lid ring and comprising a second aligner that corresponds to the at least one first aligner, wherein the first-lid ring has a circumference larger than that of the second-lid ring; the first-lid ring is for carrying the second-lid ring; and when the carrier moves toward the second-lid ring, the second-lid ring contacts the at least one wafer, the second aligner of the second-lid ring engages with the at least one first aligner of the carrier, hence the second-lid ring is aligned with the carrier.

2. The wafer-holding device according to claim 1, wherein the first-lid ring comprises a first opening; and the second-lid ring protrudes radially-inward from the first-lid ring to partially cover the first opening.

3. The wafer-holding device according to claim 1, further comprising:
a carrying member disposed on the carrier and below the at least one wafer, wherein the carrying member comprises a first-carrying portion formed with a gap notch, and a second-carrying portion disposed within the gap notch; and
at least one elevating unit connected to the first-carrying portion of the carrying member for moving the first-carrying portion and the at least one wafer related to the carrier, wherein when the at least one elevating unit moves the first-carrying portion away from the carrier, the first-carrying portion carries the at least one wafer away from the carrying surface of the carrier.

4. The wafer-holding device according to claim 1, wherein the at least one first aligner is a cavity formed with an inclined wall; and the second aligner is a protrusion formed with an inclined surface corresponding to the inclined wall of the at least one first aligner, for aligning the second-lid ring with the carrier.

5. The wafer-holding device according to claim 1, wherein the first-lid ring comprises at least one third aligner; the second-lid ring comprises at least one fourth aligner; the second aligner and the at least one fourth aligner are disposed on a bottom surface of the second-lid ring, in a manner that the at least one fourth aligner is positioned radially-outer than the second aligner; and the second-lid ring is connected to the first-lid ring in a manner that the at least one fourth aligner engages with the at least one third aligner.

6. The wafer-holding device according to claim 5, wherein the at least one third aligner of the first-lid ring comprises a cavity, and a protrusion between the cavity of the at least one third aligner and the at least one first aligner of the carrier; the at least one fourth aligner of the second-lid ring comprises a protrusion, and a cavity between the protrusion of the at least one fourth aligner and the second aligner; and the at least one third aligner and the at least one fourth aligner are for guiding and positioning the second-lid ring on the first-lid ring.

7. The wafer-holding device according to claim 5, further comprising a ring member that is connected to the carrier and that encloses the periphery of the carrying surface of the carrier, wherein the first-lid ring comprises at least one fifth aligner; the ring member comprises at least one sixth aligner; and when ring member moves with the carrier to contact the first-lid ring, the at least one fifth aligner engages with the at least one sixth aligner, such that to align the ring member with the first-lid ring.

8. The wafer-holding device according to claim 7, wherein the at least one fifth aligner of the first-lid ring is an annular protrusion formed with an inclined surface; the at least one sixth aligner of the ring member is an annular cavity formed with an inclined wall corresponding to the inclined surface of the at least one fifth aligner; and the ring member is guided to align with the first-lid ring by the inclined wall of the at least one sixth aligner and the inclined surface of the at least one fifth aligner.

9. The wafer-holding device according to claim 1, wherein the at least one first aligner of the carrier is a cavity formed with an inclined wall; the second aligner the second-lid ring is a protrusion formed with an inclined surface corresponding to the inclined wall of the at least one first aligner; and the second-lid ring is aligned with the carrier in a manner that the second aligner the second-lid ring is guided by and enters the at least one first aligner.

10. A deposition equipment, comprising:
a chamber comprising a containing space;
at least one blocking member disposed within the containing space of the chamber, wherein the at least one blocking member has an end that is formed with an opening and that has an inner flange formed at the opening;
a wafer-holding device comprising:
a carrier that comprises at least one first aligner and a carrying surface for carrying at least one wafer, wherein the at least one first aligner encloses a periphery of the carrying surface;
a first-lid ring that is disposed on the inner flange; and
a second-lid ring that is connected to the first-lid ring and that comprises a second aligner that corresponds to the at least one first aligner, wherein the first-lid ring has a circumference larger than that of the second-lid ring; the first-lid ring is for carrying the second-lid ring; and
a support member connected to the carrier for moving the carrier related to the at least one blocking member, wherein when the support member moves the carrier toward the at least one blocking member, the second-lid ring contacts the at least one wafer on the carrier, the second aligner of the second-lid ring engages with the at least one first aligner of the carrier, hence the second-lid ring is aligned with the carrier.

11. The deposition equipment according to claim 10, wherein the first-lid ring comprises a first opening; and the second-lid ring protrudes radially-inward from the first-lid ring to partially cover the first opening.

12. The deposition equipment according to claim 10, further comprising:
a carrying member disposed on the carrier and below the at least one wafer, wherein the carrying member comprises a first-carrying portion formed with a gap notch, and a second-carrying portion disposed within the gap notch, and wherein the chamber comprises a wafer passage facing the gap notch; and
at least one elevating unit connected to the first-carrying portion of the carrying member for moving the first-carrying portion and the at least one wafer related to the carrier, wherein when the at least one elevating unit moves the first-carrying portion away from the carrier, the first-carrying portion carries the at least one wafer away from the carrying surface of the carrier.

13. The deposition equipment according to claim 12, wherein the at least one first aligner is a cavity formed with an inclined wall; and the second aligner is a protrusion formed with an inclined surface corresponding to the inclined wall of the at least one first aligner, for aligning the second-lid ring with the carrier.

14. The deposition equipment according to claim 10, wherein the first-lid ring comprises at least one third aligner; the second-lid ring comprises at least one fourth aligner; the second aligner and the at least one fourth aligner are disposed on a bottom surface of the second-lid ring, in a manner that the at least one fourth aligner is positioned radially-outer than the second aligner; and the second-lid ring is connected to the first-lid ring in a manner that the at least one fourth aligner engages with the at least one third aligner.

15. The deposition equipment according to claim 14, wherein the at least one third aligner of the first-lid ring comprises a cavity, and a protrusion between the cavity of the at least one third aligner and the at least one first aligner of the carrier; the at least one fourth aligner of the second-lid ring comprises a protrusion, and a cavity between the protrusion of the at least one fourth aligner and the second aligner; and the at least one third aligner and the at least one fourth aligner are for guiding and positioning the second-lid ring on the first-lid ring.

16. The deposition equipment according to claim 14, further comprising a ring member that is connected to the carrier and that encloses the periphery of the carrying surface of the carrier, wherein the first-lid ring comprises at least one fifth aligner; the ring member comprises at least one sixth aligner; and when ring member moves with the carrier to contact the first-lid ring, the at least one fifth aligner engages with the at least one sixth aligner, such that to align the ring member with the first-lid ring.

17. The deposition equipment according to claim 16, wherein the at least one fifth aligner of the first-lid ring is an annular protrusion formed with an inclined surface; the at least one sixth aligner of the ring member is an annular cavity formed with an inclined wall corresponding to the inclined surface of the at least one fifth aligner; and the ring member is guided to align with the first-lid ring by the inclined wall of the at least one sixth aligner and the inclined surface of the at least one fifth aligner.

18. The deposition equipment according to claim 16, wherein the first-lid ring comprises a lid rim positioned radially-outer than the at least one fifth aligner; and the inner flange of the at least one blocking member is positioned between the lid rim and the at least one fifth aligner for carrying the first-lid ring.

19. The deposition equipment according to claim 10, wherein the at least one first aligner of the carrier is a cavity formed with an inclined wall; the second aligner the second-lid ring is a protrusion formed with an inclined surface corresponding to the inclined wall of the at least one first aligner; and the second-lid ring is aligned with the carrier in a manner that the second aligner the second-lid ring is guided by and enters the at least one first aligner.

20. The deposition equipment according to claim 11, further comprising a target material disposed within the containing space of the chamber and facing the carrier or the at least one wafer thereon.
